(19) United States
(12) Patent Application Publication
(10) Pub. No.: US 2023/0070679 A1
(43) Pub. Date: Mar. 9, 2023

(54) APPARATUS FOR TREATING SUBSTRATES AND TEMPERATURE CONTROL METHOD OF HEATING ELEMENTS

(71) Applicant: SEMES CO., LTD., Cheonan-si (KR)

(72) Inventors: Tae Dong PARK, Hwaseong-si (KR); Chung Woo LEE, Suwon-si (KR)

(73) Assignee: SEMES CO., LTD., Cheonan-si (KR)

(21) Appl. No.: 17/895,266

(22) Filed: Aug. 25, 2022

(30) Foreign Application Priority Data
Aug. 27, 2021 (KR) 10-2021-0113966

(51) Int. Cl. H01J 37/32; G01K 7/18; H05B 1/02; H05B 3/26; G05D 23/24

(52) U.S. Cl. CPC H01J 37/32724; G01K 7/183; H05B 1/0233; H05B 3/26; G05D 23/2401; H01J 2237/24585; H01J 2237/24564; H01J 2237/2007; H01J 2237/334; H01L 21/6833

(57) ABSTRACT

The inventive concept provides a substrate treating apparatus. The substrate treating apparatus includes a chamber having a treating space; and a support unit configured to support and heat a substrate in the treating space, and wherein the support unit includes: at least one heating element for adjusting a temperature of the substrate; a power source for generating a power applied to at least one heating element; a power supply line for transmitting the power generated by the power source to the at least one heating element; a power return line for grounding the at least one heating element; and a current measuring resistor provided on the power supply line or the power return line and used for estimating a temperature of the at least one heating element.

### CROSS-REFERENCE TO RELATED APPLICATIONS

A claim for priority under 35 U.S.C. § 119 is made to Korean Patent Application No. 10-2021-0113966 filed on Aug. 27, 2021, in the Korean Intellectual Property Office, the entire contents of which are hereby incorporated by reference.

### BACKGROUND

Embodiments of the inventive concept described herein relate to a substrate treating apparatus and a temperature control method.

In order to manufacture a semiconductor element, various treating processes such as a photolithography process, an etching process, an ion implantation process, a cleaning process, and a polishing process are performed on a substrate such as a wafer. A plasma may be used to etch a film formed on the substrate or to inject ions into the film on the substrate. A substrate treating apparatus for treating the substrate using the plasma requires an accuracy for precisely performing a substrate treatment, a repetitive reproducibility for maintaining a treating degree between substrates even when several substrates are treated, and a treating uniformity for a uniform treating degree in an entire region of a single substrate. In order to improve such an accuracy, a repetitive reproducibility, and a treating uniformity, an electrostatic chuck capable of supporting and heating the substrate has been used.

The electrostatic chuck may include a plurality of heaters, and each of the heaters may be arranged to heat regions of different substrates. Also, the heaters are independently controlled, so that a substrate temperature can be adjusted differently for each region. In recent years, in order to more precisely control the substrate temperature, the number of heaters provided in the electrostatic chuck is increasing.

Meanwhile, in order to accurately control the substrate temperature, it is required to sense a temperature of each heater and to feedback control the temperature of the heater based on a sensed temperature. However, as described above, when the number of heaters provided in the electrostatic chuck increases, the number of temperature sensors installed at the substrate treating apparatus for sensing the temperature of the heaters also increases. As the number of temperature sensors increases, not only a wiring structure of the chuck becomes complicated, but also it becomes difficult to install the temperature sensor in the chuck.

### SUMMARY

Embodiments of the inventive concept provide a substrate treating apparatus and a temperature control method of a heating element for efficiently treating a substrate.

Embodiments of the inventive concept provide a substrate treating apparatus and a temperature control method of a heating element for estimating a temperature of the heating element without a temperature sensor.

Embodiments of the inventive concept provide a substrate treating apparatus and a temperature control method for feedback controlling a temperature of a heating element based on an estimated temperature of the heating element estimated without a temperature sensor.

The technical objectives of the inventive concept are not limited to the above-mentioned ones, and the other unmentioned technical objects will become apparent to those skilled in the art from the following description.

The inventive concept provides a substrate treating apparatus. The substrate treating apparatus includes a chamber having a treating space; and a support unit configured to support and heat a substrate in the treating space, and wherein the support unit includes: at least one heating element adjusting a temperature of the substrate; a power source generating a power applied to the at least one heating element; a power supply line transmitting the power generated by the power source to the at least one heating element; a power return line grounding the at least one heating element; and a current measuring resistor provided on the power supply line or the power return line and used for estimating a temperature of the at least one heating element.

In an embodiment, a magnitude of resistance of the current measuring resistor is smaller than a magnitude of resistance of the at least one heating element.

In an embodiment, the support unit further includes at least one switch on the power supply line and/or the power supply line, and the current measuring resistor is connected in series to the at least one heating element if the at least one switch is turned on.

In an embodiment, the substrate treating apparatus further includes a control unit configured to control the support unit, and wherein the control unit includes: a resistance measurement unit configured to measure a current flowing through the current measuring resistor and measure magnitude of resistance of the at least one heating element based on the measured current; and a temperature estimation unit configured to estimate the temperature of the at least one heating element based on the magnitude of resistance of the at least one heating element measured by the resistance measurement unit.

In an embodiment, the resistance measurement unit determines the magnitude of resistance of the at least one heating element is becoming smaller as the magnitude of current flowing through the current measuring resistor is becoming greater.

In an embodiment, the temperature estimation unit estimates the temperature of the heating element based on the magnitude of resistance of the at least one heating element measured by the resistance measurement unit with reference to a reference data representing one to one correspondence between magnitude of resistance and temperature for the at least one heating element.

In an embodiment, the control unit comprises a control part configured to control the power source and/or the switch based on the temperature of the at least one heating element estimated by the temperature estimation unit.

In an embodiment, the control part generates a control signal for increasing an output of the power source if the temperature of the at least one heating element estimated by the temperature estimation unit is lower than a preset temperature.

In an embodiment, the control part generates a control signal for increasing the period during which the switch is turned on if the temperature of the at least one heating element estimated by the temperature estimation unit is lower than a preset temperature.

In an embodiment, the at least one heating element, the power supply line, and the power return line are provided in a plurality, respectively and each heating element is connected to any one of the plurality of power supply lines and any one of the plurality of power return lines but does not share a same power supply line of the plurality of power supply lines or a same power return line of the plurality of power return line.

In an embodiment, a rectifier on the power supply line and/or the power return line and preventing a reverse current toward the power source.

In an embodiment, the plurality of heating elements are arranged in a M×N matrix array when seen from above.

In an embodiment, the plurality of the heating element are arranged on a center of the support unit, and along a radial direction and a circumferential direction of the support unit to heat corresponding portions of the substrate.

The inventive concept provides a substrate treating apparatus. The substrate treating apparatus includes a chamber having a treating space; a support unit configured to support and heat a substrate in the treating space; and a plasma source generating a plasma for treating the substrate, and wherein the support unit includes: at least one heating element adjusting a temperature of the substrate; a power source generating a power applied to the at least one heating element; a power supply line transmitting the power to the at least one heating element; a power return line grounding the at least one heating element; and a current measuring resistor provided on the power supply line or the power return line and used for estimating a temperature of the at least one heating element.

In an embodiment, a ratio of magnitude of resistance of the current measuring resistor to magnitude of resistance of the at least one heating element is about 1:1000˜1:15000.

In an embodiment, support unit comprises a first plate and a second plate disposed below the first plate, and wherein the first plate includes: an insulation layer within which the at least one heating element is buried; and a dielectric layer within which an electrostatic electrode for electrostatically clamping the substrate is buried, and wherein the second plate has a fluid channel through which a cooling fluid flows.

In an embodiment, the current measuring resistor is positioned outside the insulation layer.

In an embodiment, the substrate treating apparatus further includes a control unit configured to control the support unit, and wherein the control unit includes: a resistance measuring unit configured to measure a current flowing through the current measuring resistor and measure magnitude of resistance of the at least one heating element based on the measured current; and a temperature estimation unit configured to estimate the temperature of the at least one heating element based on the magnitude of resistance of the heating element measured by the resistance measuring unit.

In an embodiment, the control unit comprises a control part configured to feedback control the temperature of the at least one heating element based on the estimated temperature of the at least one heating element estimated by the temperature estimation unit.

The inventive concept provides a method for controlling a temperature of a heating element of a support unit, the support unit comprising the heating element to adjust a temperature of a substrate; a power source generating a power applied to the heating element; a power supply line transmitting the power to the heating element; a power return line grounding the heating element; and a current measuring resistor provided on the power supply line or the power return line and used to estimate the temperature of the heating element, the method including measuring a current flowing through the current measuring resistor and magnitude of resistance of the heating element based on the measured current; estimating the temperature of the heating element based on the measured magnitude of resistance of the heating element measured; and feedback controlling the temperature of the heating element based on the estimated temperature of the heating element.

According to an embodiment of the inventive concept, a substrate may be efficiently treated.

According to an embodiment of the inventive concept, a temperature of a heating element may be estimated without a temperature sensor.

According to an embodiment of the inventive concept, a temperature of a heating element may be feedback controlled based on an estimated temperature of the heating element without a temperature sensor.

The effects of the inventive concept are not limited to the above-mentioned ones, and the other unmentioned effects will become apparent to those skilled in the art from the following description.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 schematically illustrates a substrate treating apparatus according to an embodiment of the inventive concept.

FIG. 2 is a cross-sectional view illustrating a portion of a support unit of FIG. 1.

FIG. 3 illustrates an array structure of a heating element of FIG. 2.

FIG. 4 illustrates a temperature control structure of the heating element according to an embodiment of the inventive concept.

FIG. 5 illustrates the temperature control structure of the heating element when estimating a temperature of any one of the heating elements of FIG. 4.

FIG. 6 is a flowchart illustrating a temperature control method of the heating element according to an embodiment of the inventive concept.

FIG. 7 and FIG. 8 are graphs illustrating an example of feedback controlling a temperature of the heating element based on a temperature of the heating element estimated at a feedback control step of FIG. 5.

FIG. 9 illustrates an array structure of the heating element according to another embodiment of the inventive concept.

### DETAILED DESCRIPTION

The inventive concept may be variously modified and may have various forms, and specific embodiments thereof will be illustrated in the drawings and described in detail. However, the embodiments according to the concept of the inventive concept are not intended to limit the specific disclosed forms, and it should be understood that the present inventive concept includes all transforms, equivalents, and replacements included in the spirit and technical scope of the inventive concept. In a description of the inventive concept, a detailed description of related known technologies may be omitted when it may make the essence of the inventive concept unclear.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Also, the term “exemplary” is intended to refer to an example or illustration.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

In an embodiment of the inventive concept, a substrate treating apparatus for etching a substrate using a plasma is illustrated. However, the inventive concept is not limited thereto, and may be applied to various kinds of apparatuses that perform a process of supplying the plasma into a chamber.

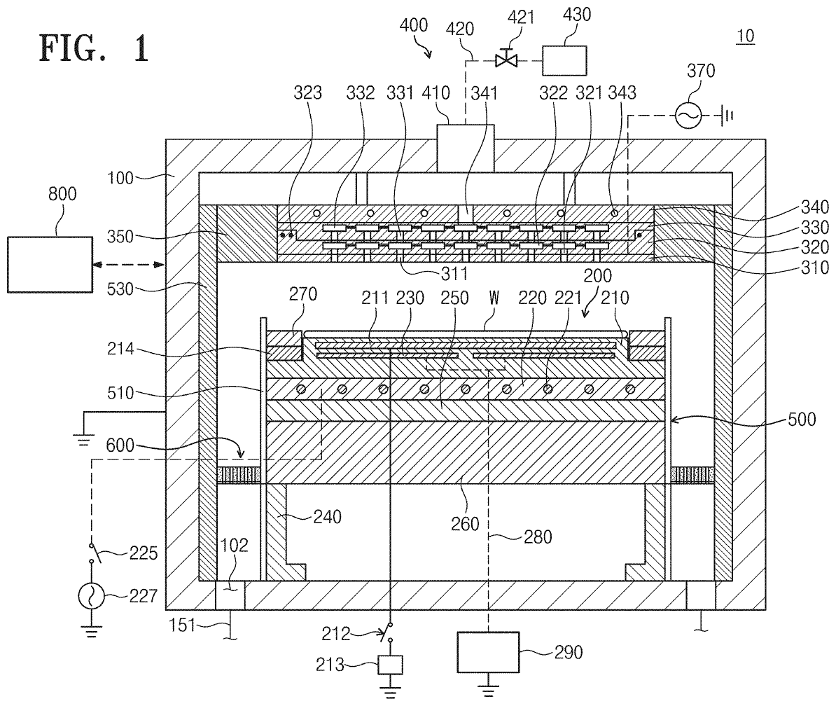

Hereinafter, an embodiment of the inventive concept will be described in detail with reference to FIG. 1 to FIG. 9.

FIG. 1 schematically illustrates a substrate treating apparatus according to an embodiment of the inventive concept.

Referring to FIG. 1, the substrate treating apparatus 10 treats a substrate W using a plasma. The substrate treating apparatus 10 may include a chamber 100, a support unit 200, a shower head unit 300, a gas supply unit 400, a plasma source, a liner unit 500, a baffle unit 600, and a control unit 800.

The chamber 100 provides a treating space in which a substrate treatment process is performed. The chamber 100 has an inner treating space. The chamber 100 is provided in a sealed form. The chamber 100 is made of a metal material. In an embodiment, the chamber 100 may be made of an aluminum material. The chamber 100 may be grounded. An exhaust hole 102 is formed on a bottom of the chamber 100. The exhaust hole 102 is connected to an exhaust line 151. The exhaust line 151 is connected to a pump (not shown). The reaction by-products generated during a process and a gas remaining in an inner space of the chamber 100 may be discharged to an outside through the exhaust line 151. An inside of the chamber 100 is depressurized to a preset pressure by the exhaust process.

A heater (not shown) is provided in a wall, for example, a side wall of the chamber 100. The heater heats the side wall of the chamber 100. The heater is electrically connected to a heating power source (not shown). The heater may be configured to undergo Joule heating (which is also known as ohmic/resistive heating) upon the application of an electric current thereto by the heating power source. For example, the heater may be configured to produce heat when an electric current passes therethrough. Heat generated by the heater is transferred to the inner space. The treating space is maintained at a preset temperature by the heat provided by the heater. The heater is provided as a coil-shaped heating wire. One or a plurality of heaters may be provided on in the side wall of the chamber 100.

The support unit 200 may support the substrate W in the treating space of the chamber 100. The support unit 200 may be an electrostatic chuck ESC that adsorbs the substrate W such as a wafer in an electrostatic manner. Selectively, the support unit 200 may clamp the substrate W in various ways, such as a mechanical clamping or a clamping by a vacuum adsorption.

Also, the support unit 200 may control a temperature of a supported substrate W. For example, the support unit 200 may increase a treating efficiency of the substrate W by increasing the temperature of the substrate W.

The support unit 200 may include a support plate 210 (an exemplary first plate), an electrode plate 220 (an exemplary second plate), a heater 230, a bottom support 240, an insulation plate 250, a ring member 270, a power line module 280, and a power source 290.

The substrate W may be placed on the support plate 210. The support plate 210 may have a disk form when viewed from above.

In some embodiments, a top surface of the support plate 210 may have a same radius as the substrate W. In some embodiments, the top surface of the support plate 210 may have a radius larger than that of the substrate W. When the substrate W is placed on the support plate 210, an edge region of the substrate W may not protrude to an outside of the support plate 210. In addition, an edge region of the support plate 210 may be stepped. An insulator 214 may be disposed at the edge region of the support plate 210 which is stepped. The insulator 214 may have a ring form when viewed from above.

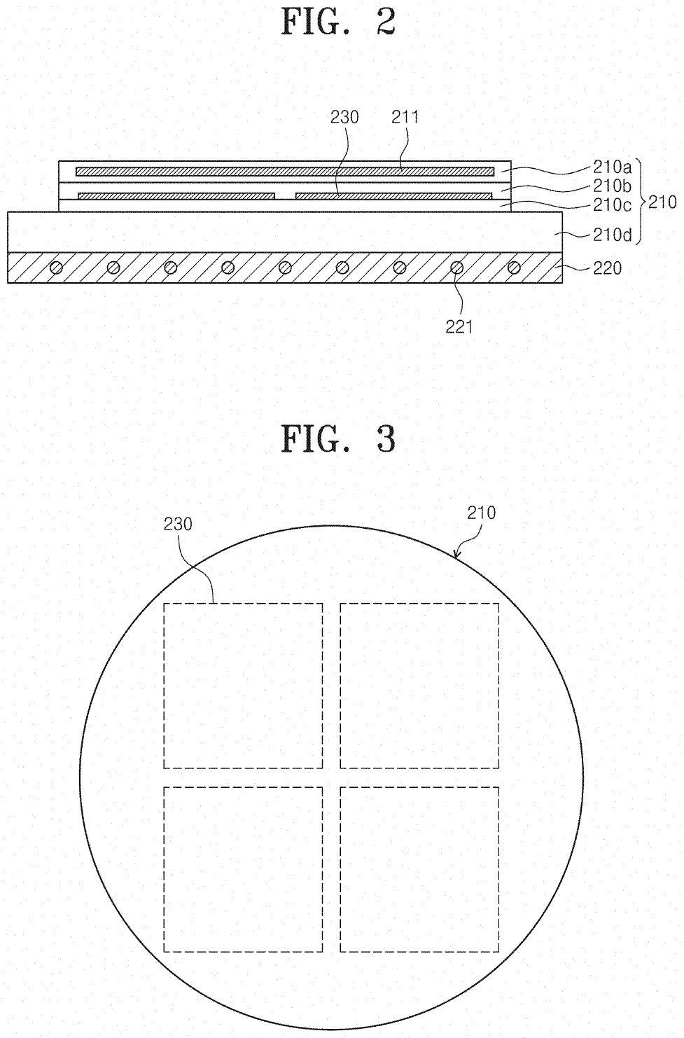

FIG. 2 is an enlarged view illustrating a portion of the support unit of FIG. 1.

Referring to FIG. 2, the support plate 210 can includes a dielectric layer 210a, a first insulation layer 210b, a second insulation layer 210c, and a heat insulation layer 210d.

An electrostatic electrode 211 may be provided in the dielectric layer 210a. For example, the electrostatic electrode 211 may be buried in the dielectric layer 210a. The electrostatic electrode 211 may be provided in a mono-polar type or a bipolar type. The electrostatic electrode 211 may be electrically connected to an electrostatic power source 213. The electrostatic power source 213 may be a DC power source. A clamping switch 212 may be installed between the electrostatic electrode 211 and the electrostatic power source 213. The electrostatic electrode 211 may be electrically connected to the electrostatic power source 213 by an on/off of the clamping switch 212. When the clamping switch 212 is turned on, a DC current may be applied to the electrostatic electrode 211. An electrostatic force may be generated between the electrostatic electrode 211 and a substrate W by a current applied to the electrostatic electrode 211. The substrate W may be clamped to the support plate 210 by the electrostatic force. The dielectric layer 210a may be formed of a material including a dielectric. For example, the dielectric layer 210a may be made of or comprise a material including a ceramic.

The first insulation layer 210b and the second insulation layer 210c may be combined with each other to form a cavity. There may be a plurality of cavities formed by the first insulation layer 210b and the second insulation layer 210c. The first insulation layer 210b may be disposed below the dielectric layer 210a. The second insulation layer 210c may be disposed below the first insulation layer 210b. A groove upwardly recessed (i.e., recessed toward the dielectric layer 210 a) is formed in the first insulation layer 210b, and the second insulation layer 210c is disposed below the first insulation layer 210b to form the cavities therebetween. A heating element 230 may be disposed in each of the cavities formed by the first insulation layer 210b and the second insulation layer 210c. Although FIG. 2 illustrates that the groove is formed at the first insulation layer 210b, the second insulation layer 210c may have grooves and/or both the first insulation layer 210 b and the second insulation layer 210c may have grooves. The first insulation layer 210b and the second insulation layer 210c may be a polymer material, an inorganic material, a ceramic, for example, a silicon oxide, an alumina, an yttrium, an aluminum nitride, other suitable materials, and/or combinations thereof.

The heat insulation layer 210d may be disposed below the second insulation layer 210c. The heat insulation layer 210d may function as a thermal barrier. For example, it is possible to minimize a transfer of a heat generated by the heating element 230 to a bottom portion of the support unit 200. In addition, it is possible to minimize a transfer of a coldness of a cooling fluid flowing in a top fluid channel 221, which is a cooling fluid channel, to the insulation layers 210b and 210c where the heating element 230 is disposed.

The heating element 230 may control a temperature of the substrate W. The heating element 230 may heat the substrate W. The heating element 230 may generate a heat by receiving a power generated by a power source 290 to be described later through a power line module 280. The heating element 230 may be disposed in a cavity formed by the first insulation layer 210b and the second insulation layer 210c. A plurality of heating elements 230 may be provided. For example, the heating elements 230 may each heat different regions of the substrate W, respectively. For example, a first portion of the heating elements 230 may heat a first region of the substrate W. In addition, a second portion of the heating elements 230 may heat a second region of the substrate W.

The heating elements 230 may be arranged in a matrix array to control a temperature of each of the regions of the substrate W as illustrated in FIG. 3. Although FIG. 3 illustrates that four heating elements 230 are provided in a 2×2 array, the inventive concept is not limited thereto. For example, the heating element 230 may be provided in an M×N array wherein M, N≥2. The total number of heating elements 230 may be variously changed as necessary.

In addition, the heating element 230 may have a plate shape. For example, the heating element 230 may be referred to as a heating plate. Each heating element 230 may have various shapes such as a rectangular shape as illustrated in FIG. 3, a pentagonal shape, etc. In addition, the heating element 230 may be a resistive heater, such as a polyimide heater, a silicone rubber heater, a mica heater, a metal heater, a ceramic heater, a semiconductor heater, or a carbon heater.

In addition, an area of the heating element 230 may be larger than or corresponding to an area of a die manufactured on the substrate W. For example, each heating element 230 may be sized such that its top surface entirely covers the top surface of corresponding die which will be manufactured on the substrate W. For example, the top surface area of each heating element 230 may be 2 cm² to 3 cm². In addition, a thickness of each heating element 230 may range from 2 micrometers to 1 millimeter, and more particularly, from 5 micrometers to 80 micrometers. In addition, when viewed from above, a total area occupied by the heating elements 230 may be 50% to 90% of an area of a top surface of the support unit 200, for example, the top surface of the support plate 210. For example, when viewed from above, the total area occupied by the heating elements 230 may be 90% of a top surface of the support plate 210.

A temperature control structure of the heating element 230 and a temperature control method of the heating element 230 may be further illustrated.

Referring back to FIG. 1, the electrode plate 220 may be provided below the support plate 210. A top surface of the electrode plate 220 may be in contact with a bottom surface of the support plate 210. The electrode plate 220 may have a disk shape. The electrode plate 220 is made of a conductive material. In an embodiment, the electrode plate 220 may be made of an aluminum material. A top fluid channel 221 which is a channel through which a cooling fluid flows may be formed within the electrode plate 220. The top fluid channel 221 mainly cools the support plate 210. A cooling fluid may be supplied to the top fluid channel 221. In an embodiment, the cooling fluid may a cooling water or a cooling gas. In addition, the electrode plate 220 may be an embodiment of the cooling plate.

The electrode plate 220 may be provided as a metal plate. The electrode plate 220 may be electrically connected to a bottom power source 227. The bottom power source 227 may be provided as a high frequency power source for generating a high frequency power. The high frequency power source may be provided as an RF power source. The RF power source may be provided as a high bias power RF power source. The electrode plate 220 may selectively receive the high frequency power from the bottom power source 227 by switching the bottom switch 225. Selectively, the electrode plate 220 may be grounded.

An insulation plate 250 may be disposed below the electrode plate 220. The insulation plate 250 may be provided in a circular plate form. The insulation plate 250 may be provided with an area corresponding to that of the electrode plate 220. The insulation plate 250 may be provided as an insulation plate. In an embodiment, the insulation plate 250 may be provided as a dielectric.

The bottom support 240 is disposed below the electrode plate 220. The bottom support 240 is disposed below the bottom plate 260. The bottom support 240 is provided in a ring shape.

The bottom plate 260 is disposed below the insulation plate 250. The bottom plate 260 may be made of an aluminum material. The bottom plate 260 may be provided in a circular form when viewed from above. The bottom plate 260 may have an inner space. A lift pin module (not shown) that moves the substrate W from an external transfer member to the support plate 210, etc. can be positioned in the inner space of the bottom plate 260.

The ring member 270 is disposed at an edge region of the support unit 200. The ring member 270 has a ring form. The ring member 270 is provided to surround a top portion of the support plate 210. The ring member 270 may be provided on the insulator 214 disposed in the edge region of the support plate 210. The ring member 270 may be provided as a focus ring.

The shower head unit 300 is disposed above the support unit 200 inside the chamber 100. The shower head unit 300 is positioned to face the support unit 200. The shower head unit 300 includes a shower head 310, a gas injection plate 320, a cover plate 330, a top plate 340, and an insulation ring 350.

The shower head 310 is positioned to be spaced downwardly apart from a top surface of the chamber 100 by a preset distance. The shower head 310 is disposed above the support unit 200. A preset space is formed between the shower head 310 and the top surface of the chamber 100. The shower head 310 may be provided in a plate form having a constant thickness. A bottom surface of the shower head 310 may be anodized to prevent an arc generation due to a plasma. A cross-section of the shower head 310 may be provided to have a same form and cross-sectional area as the support unit 200. The shower head 310 includes a plurality of injection holes 311. The injection hole 311 penetrates the top and bottom surfaces of the shower head 310 in an up/down direction.

The shower head 310 may be made of a material that reacts with a plasma generated from a gas supplied by the gas supply unit 400 to generate a compound. For example, the shower head 310 may be provided as a material that reacts with an ion having a highest electronegativity among ions included in the plasma to generate a compound. For example, the shower head 310 may be made of a material including a silicon. In addition, the compound produced by a reaction between the shower head 310 and plasma may be a silicon tetrafluoride.

The shower head 310 may be electrically connected to the top power source 370. The top power supply 370 may be provided as a high frequency power supply. Selectively, the shower head 310 may be electrically grounded.

The gas injection plate 320 is positioned on a top surface of the shower head 310. The gas injection plate 320 is positioned to be spaced apart from the top surface of the chamber 100 by a preset distance. The gas injection plate 320 may be provided in a plate form having a constant thickness. A heater 323 is provided in an edge area of the gas injection plate 320. The heater 323 heats the gas injection plate 320.

The gas injection plate 320 is provided with a diffusion region 322 and an injection hole 321. The diffusion region 322 evenly spreads a gas supplied from above to the injection hole 321. The diffusion region 322 is connected to the injection hole 321 disposed below. Adjacent diffusion regions 322 are connected to each other. Adjacent injection hole 321 is connected to the diffusion region 322 and penetrates a bottom surface in a top/down direction.

The injection hole 321 is positioned to face the injection hole 311 of the shower head 310. The gas injection plate 320 may include a metal material.

The cover plate 330 is positioned above the gas injection plate 320. The cover plate 330 may be provided in a plate form having a constant thickness. The cover plate 330 is provided with a diffusion region 332 and an injection hole 331. The diffusion region 332 evenly spreads the gas supplied from above to the injection hole 331. The diffusion region 332 is connected to the injection hole 331 disposed below. Adjacent diffusion regions 332 are connected to each other. The injection hole 331 is connected to the diffusion region 332 and penetrates the bottom surface in the top/down direction.

The top plate 340 is disposed above the cover plate 330. The top plate 340 may be provided in a plate form having a constant thickness. The top plate 340 may have the same size as the cover plate 330. A supply hole 341 is formed in a center of the top plate 340. The supply hole 341 is a hole through which a gas passes. The gas passing through the supply hole 341 is supplied to the diffusion region 332 of the cover plate 330. A cooling fluid channel 343 is formed within the top plate 340. The cooling fluid may be supplied to the cooling fluid channel 343. In an embodiment, the cooling fluid may be provided as a cooling water.

Also, the shower head 310, the gas injection plate 320, the cover plate 330, and the top plate 340 may be supported by a rod. For example, the shower head 310, the gas injection plate 320, the cover plate 330, and the top plate 340 may be coupled to each other and supported by the rod fixed to a top surface of the top plate 340. In addition, the rod may be coupled to an inside of the chamber 100.

The insulation ring 350 is disposed to surround a circumference of the shower head 310, the gas injection plate 320, the cover plate 330, and the top plate 340. The insulation ring 350 may be provided in a circular ring form. The insulation ring 350 may be made of a non-metallic material. The insulation ring 350 is positioned to overlap the ring member 270 when viewed from above. When viewed from above, a surface where the insulation ring 350 and the shower head 310 are in contact is positioned to overlap a top region of the ring member 270.

The gas supply unit 400 supplies a gas to inside of the chamber 100. The gas supplied by the gas supply unit 400 may be excited to a plasma state by a plasma source. In addition, the gas supplied by the gas supply unit 400 may be a gas containing a fluorine. For example, the gas supplied by the gas supply unit 400 may be a carbon tetrafluoride.

The gas supply unit 400 includes a gas supply nozzle 410, a gas supply line 420, and a gas storage unit 430. The gas supply nozzle 410 is installed at a center of the top surface of the chamber 100. An injection hole is formed on a bottom surface of the gas supply nozzle 410. The injection port supplies a process gas into the chamber 100. The gas supply line 420 connects the gas supply nozzle 410 to the gas storage unit 430. The gas supply line 420 supplies the process gas stored at the gas storage unit 430 to the gas supply nozzle 410. A valve 421 is installed at the gas supply line 420. The valve 421 opens and closes the gas supply line 420 and adjusts a flow rate of the process gas supplied through the gas supply line 420.

The plasma source excites the process gas in the chamber 100 in the plasma state. In an embodiment of the inventive concept, a capacitively coupled plasma (CCP) source is used as the plasma source. The capacitively coupled plasma source may include a top electrode and a bottom electrode inside the chamber 100. The top electrode and the bottom electrode may be disposed vertically in parallel with each other in the chamber 100. One electrode among both electrodes may apply a high frequency power, and the other electrode may be grounded. An electromagnetic field is formed in a space between both electrodes, and a process gas supplied to the space may be excited to the plasma state. A substrate W treatment process is performed using this plasma. According to an embodiment, the top electrode of the CCP source may be provided as the shower head unit 300, and the bottom electrode of the CCP source may be provided as the electrode plate described above. The high frequency power may be applied to the bottom electrode, and the top electrode may be grounded. Alternatively, the high-frequency power may be applied to both the top electrode and the bottom electrode. Accordingly, an electromagnetic field is generated between the top electrode and the bottom electrode. A generated electromagnetic field excites the process gas provided into the chamber 100 to the plasma state.

A liner unit 500 prevents an inner wall of the chamber 100 and the support unit 200 from being damaged during a process. The liner unit 500 prevents impurities generated during the process from being deposited on the inner wall and the support unit 200. The liner unit 500 includes an inner liner 510 and an outer liner 530.

The outer liner 530 is provided on the inner wall of the chamber 100. The outer liner 530 has a space in which a top surface and a bottom surface are open. The outer liner 530 may be provided in a cylindrical form. The outer liner 530 may have a radius corresponding to an inner surface of the chamber 100. The outer liner 530 is provided along the inner surface of the chamber 100.

The outer liner 530 may be made of an aluminum material. The outer liner 530 protects an inner surface of the body 110. In a process of exciting the process gas, an arc discharge may be generated in the chamber 100. The arc discharge damages the chamber 100. The outer liner 530 protects the inner surface of the body 110 to prevent the inner surface of the body 110 from being damaged by the arc discharge.

The inner liner 510 is provided to surround the support unit 200. The inner liner 510 is provided in a ring form. The inner liner 510 is provided to surround all of the support plate 210, the electrode plate 220, and the bottom support 240. The inner liner 510 may be made of an aluminum material. The inner liner 510 protects an outer surface of the support unit 200.

A baffle unit 600 is positioned between the inner wall of the chamber 100 and the support unit 200. The baffle is provided in an annular ring form. A plurality of through holes are formed at the baffle. A gas provided in the chamber 100 passes through the through holes of the baffle and is exhausted through the exhaust hole 102. A flow of the gas may be controlled according to a form of the baffle and a form of the through holes.

A control unit 800 may control a substrate treating apparatus 10. The control unit 800 may control the substrate treating apparatus 10 such that the substrate treating apparatus 10 performs a plasma treating process on the substrate W. Also, the control unit 800 may comprise a process controller consisting of a microprocessor (computer) that executes a control of the substrate treating apparatus 10, a user interface such as a keyboard via which an operator inputs commands to manage the substrate treating apparatus 10, and a display showing the operation situation of the substrate treating apparatus 10, and a memory unit storing a treating recipe, i.e., a control program to execute treating processes of the substrate treating apparatus by controlling the process controller or a program to execute components of the substrate treating apparatus according to data and treating conditions. In addition, the user interface and the memory unit may be connected to the process controller. The treating recipe may be stored in a storage medium of the storage unit, and the storage medium may be a hard disk, a portable disk, such as a CD-ROM or a DVD, or a semiconductor memory, such as a flash memory.

Hereinafter, a temperature control structure of the heating element 230 according to an embodiment of the inventive concept will be illustrated in detail.

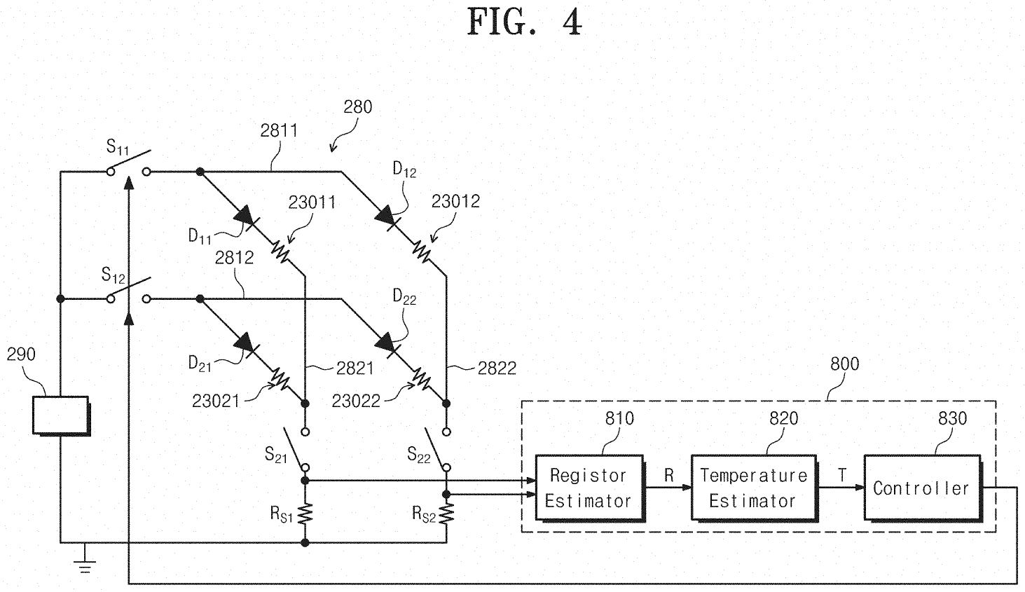

FIG. 4 is a view illustrating the temperature control structure of the heating element according to an embodiment of the inventive concept. Referring to FIG. 4, as described above, the heating element 230 may be provided in the support plate 210. The heating elements 230 may receive a power from the power source 290 to generate a heat. A power supplied by the power source 290 may be transmitted to the heating element 230 by the power line module 280.

As described above, a plurality of heating elements 230 may be provided, and the heating elements 230 may be arranged in a matrix array to adjust a temperature of each of the regions of the substrate W. For example, the heating element 230 may be arranged along the M×N array as described above. Hereinafter, the heating element 230 disposed on the M×N array (M, N) may be referred to as a M-N heating element 230MN. For example, a heating element 230 disposed at the M×N array 1 and 1 may be referred to as a 1-1 heating element 23011. A heating element 230 disposed at the M×N array 1 and 2 may be referred to as a 1-2 heating element 23012. In FIG. 4, for convenience of explanation, the heating elements 230 are arranged along the 2×2 array as an example.

The power line module 280 may transmit a power generated by the power source 290 to the heating elements 230. The power line module 280 may include a power supply line 281 and a power return line 282.

The power supply line 281 may be a line for supplying the power generated by the power source 290 to the heating element 230. The power supply line 281 may refer to a line provided at a front end of the heating element 230 based on a path at which a current flows. Also, the power supply line 281 may be electrically connected to a plurality of heating elements 230, e.g., input side of the heating element. For example, the power supply line 281 may be electrically connected to the heating elements 230 disposed in a same row.

A plurality of power supply lines 281 may be provided. For example, the power supply line 281 may be provided with a number of M, which is the number of rows of the M×N array of the heating elements. For example, the power supply line 281 electrically connected to the group of heating elements 230 disposed in the first row of the M×N array may be referred to as the first power supply line 2811. In addition, the power supply line electrically connected to the group of the heating element 230 disposed in the second row of the M×N array may be referred to as the second supply line 2812.

The power return line 282 may be ground the heating elements 230. The power return line 281 may refer to a line provided at a back end of the heating element 230 with respect to a path at which the current flows. In addition, the power return line 282 may be electrically connected to the plurality of heating elements 230, e.g., the output side of the heating element. For example, the power return line 282 may be electrically connected to the heating elements 230 disposed in a same column.

A plurality of power return lines 282 may be provided. For example, a number of N power return lines 282 may be provided, which are the number of column of the M×N array of the heating elements. For example, the power return line 282 electrically connected to a group of the heating elements 230 disposed in a first column of the M×N array may be referred to as a first power return line 2821. In addition, the power return line 282 electrically connected to the group of heating elements 230 disposed in the first column of the M×N array may be referred to as a second power return line 2822.

In addition, no two heating elements 230 are connected to a same one of the power supply lines 281 and a same one of the power return lines 282. For example, for the 1-1 heating element 23011, it may be electrically connected to the first power supply line 2811 and electrically connected to the first power return line 2821. For the 1-2 heating element 23012, it can be electrically connected to the first power supply line 2811 and electrically connected to the second power return line 2822. Comparing the 1-1 heating element 23011 and the 1-2 heating element 23012 with each other, the first power supply line 2811 is shared, but the power return line 282 is not shared. This is to independently control a heat generation of each heating element 230, while preventing a connection between the power supply line 281 and the power return line 282 from becoming complicated. If the connection between the power supply line 281 and the power return line 282 becomes complicated, problems such as a short circuit may frequently occur, and a maintenance may be difficult. However, according to an embodiment of the inventive concept, each of the heating elements 230 are connected to any one of the power supply lines 281 and any one of the power return lines 282, and since the heating elements 230 do not share a same power supply line of the plurality of the power supply line and a same power return line of the plurality of power return line, an independent control and simplified connection of the heating element 230 can be actualized.

In addition, a rectifier D may be installed at the power supply line 281. The rectifier D may be installed at the power supply line 281, and may be installed at a front end of the heating element 230. The rectifier D may be provided to correspond to each heating element 230. For example, a plurality of rectifiers D may be provided to correspond to each of the heating elements 230. A rectifier D corresponding to the 1-1 heating element 23011 may be referred to as a 1-1 rectifier D11. A rectifier D corresponding to the 1-2 heating element 23012 may be referred to as a 1-2 rectifier D12. A rectifier D corresponding to the M-N heating element 230MN may be referred to as a M-N rectifier DMN.

A power generated by the power source 290 may be selectively transmitted to the heating element 230 by a controlling of switches S. For example, a switch S may include a 1-1 switch S11 installed at the first power supply line 2811; a 1-2 switch S12 installed at a second power supply line 2812; a 2-1 switch S21 installed at the first power return line 2821; and a 2-2 switch 22 installed at the second power return line 2822. The power may be selectively applied to the heating element 230 according to an on/off control of the switches S.

For example, in order to apply the power to the 1-1 heating element 23011, the 1-1 switch S11 and the 2-1 switch S21 may be turned on and remaining switches S may be turned off. In addition, in order to apply the power to the 1-1 heating element 23011 and the 1-2 heating element 23012, the 1-1 switch S11, the 2-1 switch S21, and the 2-2 switch S22 may be turned on and remaining switches S may be turned off. A control unit 800 to be described later can control the heating elements 230 independently by selectively forming closed circuits by combining an on/off of these switches S.

In addition, a current measuring resistor RS may be installed at the power supply line 281 or the power return line 282. For example, the current measuring resistor RS may be installed at the power return line 282. For example, the current measuring resistor RS may include a first current measuring resistor RS1 installed at a rear end of the 2-1 switch S21 and a second current measuring resistor RS2 installed at a rear end of the 2-2 switch S22. In addition, the current measuring resistor RS may be disposed outside of the dielectric layer 210a and the insulation layers 210b and 210c described above.

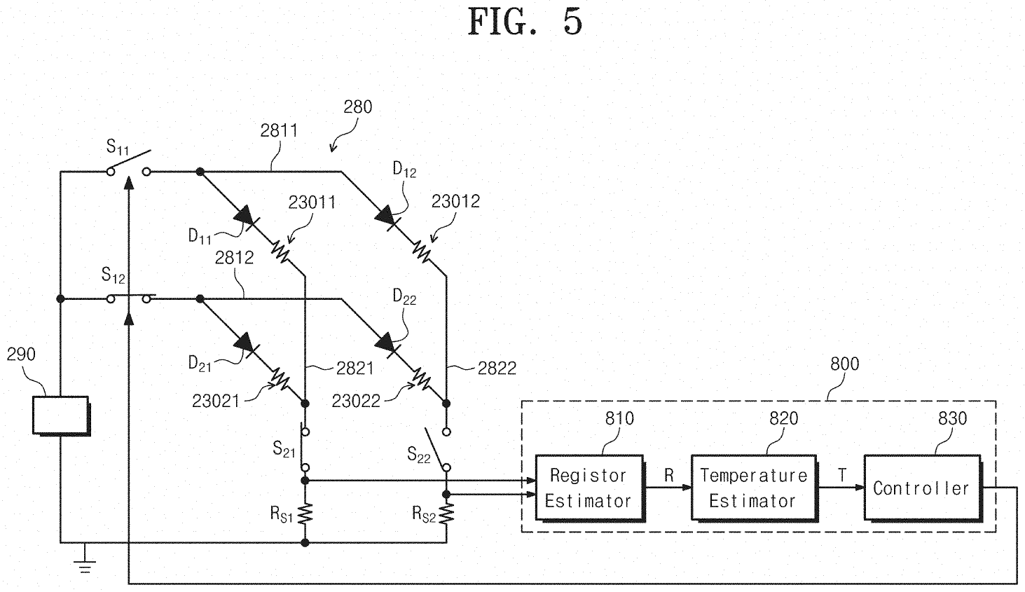

The current measuring resistor RS can be a shunt resistor for measuring a current (more specifically, a magnitude of a current) flowing at a closed circuit. The current measuring resistor RS can be connected in series with the heating element 230 when the closed circuit is formed to apply the power to some of the plurality of heating elements 230. For example, when the power is applied to the 2-1 heating element 23021 as shown in FIG. 5, the 1-2 switch S12 and the 2-1 switch S21 may be turned on. When the 1-2 switch S12 and the 2-1 switch S211 are turned on, the 2-1 heating element 23021 and the first current measuring resistor RS1 may be connected in series with each other. In this case, the same current may flow through the 2-1 heating element 23021 and the first current measuring resistor RS1.

In addition, the current measuring resistor RS may have a very small resistance value. When the current measuring resistor RS and the heating element 230 are contained in the same closed circuit (i.e., when the current measuring resistor RS is connected in series with the heating element 230), the voltage is divided among serially connected the heating element 230 and the current measuring resistor RS in direct proportion to their resistance values. The greater the magnitude of resistance value of the current measuring resistor RS is, the greater the voltage is divided thereto, and thus it may be difficult to appropriately control a temperature of the heating element 230.

Accordingly, the magnitude of resistance of the current measuring resistor RS in accordance with an embodiment of this invention may be smaller than magnitude of resistance of the heating element 230. For example, the magnitude of the resistance of the current measuring resistor RS may be negligibly small compared to the magnitude of the resistance of the heating element 230. For example, a ratio of the resistance of the current measuring resistor RS to the resistance of the heating element 230 may be about 1:1000˜1:15000. For example, if the resistance of the heating element 230 is 10 [Ω], the resistance of the current measuring resistor RS may be 1 m[Ω] to 100 m[Ω].

The control unit 800 may include a resistance measurement unit 810, a temperature estimation unit 820, and a control part 830. The resistance measurement unit 810 may measure a current flowing in the current measuring resistor RS, and may measure a magnitude of resistance of the heating element 230 based on the measured current. The resistance measurement unit 810 may perform a resistance measurement step S10 to be described later. The temperature estimation unit 820 may estimate the temperature of the heating element 230 based on the magnitude of resistance of the heating element 230 measured by the resistance measurement unit 810. The temperature estimation unit 820 may perform a temperature estimation step S20 to be described later. The control part 830 may feedback-control the temperature of the heating element 230 based on the estimated temperature of the heating element 230 estimated by the temperature estimation unit 820. For example, the control part 830 may generate a control signal for feedback-controlling at least one of the power source 290 or the switch S.

Hereinafter, a temperature control method of the heating element 230 according to an embodiment of the inventive concept will be described in detail.

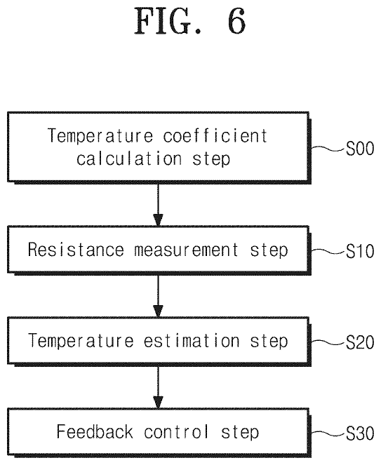

FIG. 6 is a flowchart illustrating a temperature control method of a heating element according to an embodiment of the inventive concept. Referring to FIG. 6, the temperature control method of the heating element 230 of the inventive concept may include a temperature coefficient calculation step S00, a resistance measurement step S10, a temperature estimation step S20, and a feedback control step S30

The temperature coefficient calculation step S00 may be performed in advance before a treatment of a substrate W is performed. The temperature coefficient calculation step S00 may be performed before the substrate W is treated, and may be performed for each heating element 230. A temperature coefficient α for each of the heating elements 230 may be previously stored at the control unit 800.

The temperature coefficient calculation step S00 may calculate a temperature resistance coefficient α to be used in the temperature estimation step S20 to be described later. The temperature resistance coefficient α may be a coefficient indicating a rate of change in a resistance value according to a temperature change of the heating element 230. The temperature resistance coefficient α may be calculated based on an information including a change in magnitude of the resistance of the heating element 230 measured by changing the temperature of the heating element 230.

The temperature change of the heating element 230 may occur by changing a temperature of a cooling fluid supplied to a cooling fluid channel 221 of the electrode plate 220. In addition, the resistance of the heating element 230 may directly measured using a measuring instrument or the resistance of the heating element 230 may measured using Ohm's Law to measure the voltage applied to both ends of the current measurement resistor RS. In this case, in order to increase an influence of the cooling fluid, the magnitude of voltage generated by the power source 290 may be as small as possible.

The temperature resistance coefficient α may be calculated by the following equation.

$$α = \frac{R 2 - R 1}{R 1 ( T 2 - T 1 )} ⨯ 1,000,000 [ \frac{PPM}{°C} ]$$

[α: temperature resistance coefficient, R1: designed resistance of the heating element 230, R2: measured resistance of the heating element 230, T1: designed temperature, T2: measured temperature]

The designed resistance R1 may mean the designed resistance of the heating element 230. The designed resistance R1 may mean a resistance of the heating element 230 at the designed temperature T1. For example, the heating element 230 may be designed to have 10Ω at 25° C. An information on the designed resistance R1 and the designed temperature T1 may be obtained. The measured resistance R2 may mean the magnitude of resistance measured when the temperature of the heating element 230 is the measured temperature T2.

In the resistance measurement step S10, a resistance R of the heating element 230 may be measured. The resistance of the heating element 230 may be calculated using Ohm's law. For example, as shown in FIG. 5, when the heating element 230 and the current measuring resistor RS are connected in series and a closed circuit is configured, the resistance R of the heating element 230, the resistance RS of the current measuring resistor RS, and a current I and a voltage V flowing in the closed circuit may have the following relationship.

$$R + RS = \frac{V}{I}$$

[R: Resistance of the heating element 230, RS: Resistance of the current measuring resistor RS, V: Power, I: Current]

The resistance measurement unit 810 may determine that as the magnitude of current flowing through the current measuring resistor RS increases, the magnitude of resistance of the heating element 230 decreases. In addition, since the magnitude of resistance of current measuring resistor RS is negligibly small compared with a resistance R value of the heating element 230, the magnitude of resistance R of the heating element 230 may be relatively accurately derived through a ratio of voltage to current.

In the temperature estimation step S20, the temperature of the heating element 230 may be estimated. In the temperature estimation step S20, the temperature of the heating element 230 may be estimated through a reference data previously stored in the control unit 800 and measured magnitude of resistance R of the heating element 230 in the resistance measurement step S10. For example, an estimated temperature T of the heating element 230 estimated in the temperature estimation step S20 and the measured magnitude of resistance of the heating element 230 measured in the resistance measurement step S10 may have the following relationship.

$$T = T 0 + \frac{1}{α} ( \frac{R}{R 0} - 1 ) + c$$

[T: estimated temperature of heating element 230, T0: initial temperature of heating element 230, R: measured magnitude of resistance of heating element 230, R0: initial resistance of heating element 230, α: temperature resistance coefficient, c: calibration constant]

In the reference data previously stored in the control unit 800, an information on the magnitude of resistance (initial resistance, R0) of the heating element 230 at a specific temperature (initial temperature, T0) may be previously stored. The temperature estimation unit 820 may estimate the temperature of the heating element 230 based on a previously stored reference data on the heating element 230 and the measured magnitude of resistance R of the heating element 230 measured by the resistance measurement unit 810.

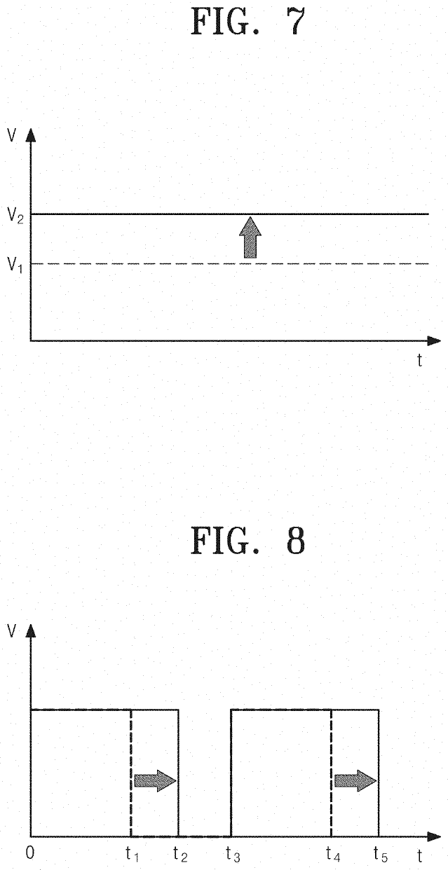

The control part 830 may feedback-control the temperature of the heating element 230 based on the estimated temperature of the heating element 230 estimated by the temperature estimation unit 820. For example, the control part 830 may control an output of the power source 290 based on the estimated temperature of the heating element 230 estimated by the temperature estimation unit 820. For example, when the estimated temperature of the heating element 230 is lower than a preset temperature, as illustrated in FIG. 7, the control part 830 may generate a control signal that increases the output of the power source 290 from a first voltage V1 to a second voltage V2.

In addition, when the estimated temperature of the heating element 230 is lower than a preset temperature, as illustrated in FIG. 8, the control part 830 may generate a control signal for increasing a period during which the switch S is turned on so that the power source 290 may apply the power to the heating element 230 over extended time.

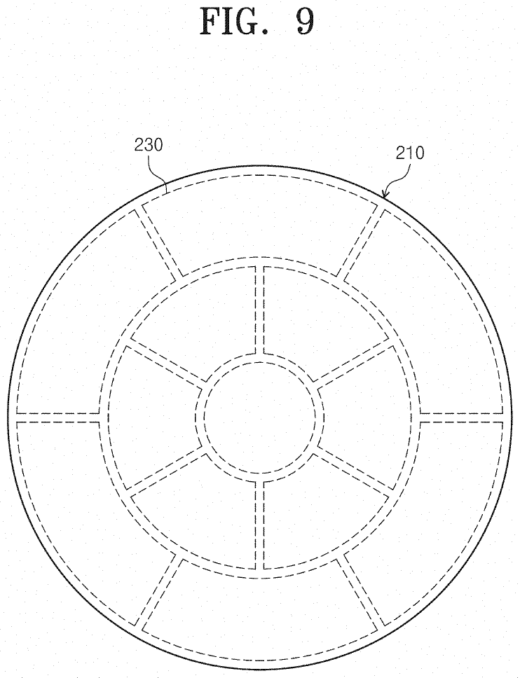

In the above-described example, the heating elements 230 are arranged in a matrix array, but the inventive concept is not limited thereto. For example, as shown in FIG. 9, the heating elements may be disposed on a center of the support unit (i.e., support plate 210), along the radial direction of the support plate 210 and along the circumferential direction of the support plate 210. For example, some of the heating elements 230 may be disposed in a central region of the support plate 210 when viewed from above, and some of the heating elements 230 may be disposed in an edge region of the support plate 210. For example, some of the heating elements 230 may be disposed at a first edge region surrounding the central region, and some of the heating elements 230 may be disposed at a second edge region surrounding the first edge region. In addition, the heating elements 230 disposed in the edge region of the support plate 210 may be arranged to be spaced apart from each other along a circumferential direction of the support plate 210.

In general, as a method for controlling the temperature of a heater such as the heating element 230, an offset compensation method for compensating a dropped temperature of the heating element 230 by applying a preset voltage to the heating element 230 is used. For example, in the offset compensation method, a voltage of a preset size is applied to the heating element 230 for a preset time. This method is a temperature compensation method that may be simply applied when environmental changes around the heating element 230 are extremely limited.

However, aging may occur in the heating element 230, and an environmental change may occur around the heating element 230 according to a temperature change around the support unit 200. Accordingly, it is preferable to use a temperature sensor to feedback control the heating element 230.

However, as described above, as the number of heating elements 230 increases, installing a plurality of temperature sensors causes various mechanical limitations and is disadvantageous in terms of cost. However, according to an embodiment of the inventive concept, the current measuring resistor RS is installed on an existing power supply line 281 or power return line 282, a current flowing in the current measuring resistor RS is measured, and based on this, a magnitude of resistance and a temperature of the heating element 230 may be estimated. That is, it is possible to estimate the temperature of the heating element 230 without installing a temperature sensor. Accordingly, mechanical restrictions for installing a plurality of temperature sensors and problems caused by installing the plurality of temperature sensors may be solved. In addition, the inventive concept enables a feedback control of the heating element 230 according to an estimated temperature of the heating element 230 even when it is difficult or impossible to install a temperature sensor, thereby improving a robustness of the heating element 230 according to an outer environment.

The effects of the inventive concept are not limited to the above-mentioned effects, and the unmentioned effects can be clearly understood by those skilled in the art to which the inventive concept pertains from the specification and the accompanying drawings.

Although the preferred embodiment of the inventive concept has been illustrated and described until now, the inventive concept is not limited to the above-described specific embodiment, and it is noted that an ordinary person in the art, to which the inventive concept pertains, may be variously carry out the inventive concept without departing from the essence of the inventive concept claimed in the claims and the modifications should not be construed separately from the technical spirit or prospect of the inventive concept.

1. A substrate treating apparatus comprising:
a chamber having a treating space; and
a support unit configured to support and heat a substrate in the treating space, and
wherein the support unit comprises:
at least one heating element adjusting a temperature of the substrate;
a power source generating a power applied to the at least one heating element;
a power supply line transmitting the power generated by the power source to the at least one heating element;
a power return line grounding the at least one heating element; and
a current measuring resistor provided on the power supply line or the power return line and used for estimating a temperature of the at least one heating element.

2. The substrate treating apparatus of claim 1, wherein a magnitude of resistance of the current measuring resistor is smaller than a magnitude of resistance of the at least one heating element.

3. The substrate treating apparatus of claim 2, wherein the support unit further comprises at least one switch on the power supply line and/or the power supply line, and
the current measuring resistor is connected in series to the at least one heating element if the at least one switch is turned on.

4. The substrate treating apparatus of claim 1, further comprising a control unit configured to control the support unit, and
wherein the control unit comprises:
a resistance measurement unit configured to measure a current flowing through the current measuring resistor and measure magnitude of resistance of the at least one heating element based on the measured current; and
a temperature estimation unit configured to estimate the temperature of the at least one heating element based on the magnitude of resistance of the at least one heating element measured by the resistance measurement unit.

5. The substrate treating apparatus of claim 4, wherein the resistance measurement unit determines the magnitude of resistance of the at least one heating element is becoming smaller as the magnitude of current flowing through the current measuring resistor is becoming greater.

6. The substrate treating apparatus of claim 4, wherein the temperature estimation unit estimates the temperature of the heating element based on the magnitude of resistance of the at least one heating element measured by the resistance measurement unit with reference to a reference data representing one to one correspondence between magnitude of resistance and temperature for the at least one heating element.

7. The substrate treating apparatus of claim 4, wherein the control unit comprises a control part configured to control the power source and/or the switch based on the temperature of the at least one heating element estimated by the temperature estimation unit.

8. The substrate treating apparatus of claim 7, wherein the control part generates a control signal for increasing an output of the power source if the temperature of the at least one heating element estimated by the temperature estimation unit is lower than a preset temperature.

9. The substrate treating apparatus of claim 7, wherein the control part generates a control signal for increasing the period during which the switch is turned on if the temperature of the at least one heating element estimated by the temperature estimation unit is lower than a preset temperature.

10. The substrate treating apparatus of claim 4, wherein the at least one heating element, the power supply line, and the power return line are provided in a plurality, respectively and each heating element is connected to any one of the plurality of power supply lines and any one of the plurality of power return lines but does not share a same power supply line of the plurality of power supply lines or a same power return line of the plurality of power return line.

11. The substrate treating apparatus of claim 10, wherein a rectifier on the power supply line and/or the power return line and preventing a reverse current toward the power source.

12. The substrate treating apparatus of claim 10, wherein the plurality of heating elements are arranged in a M×N matrix array when seen from above.

13. The substrate treating apparatus of claim 10, wherein the plurality of the heating element are arranged on a center of the support unit, and along a radial direction and a circumferential direction of the support unit to heat corresponding portions of the substrate.

14. A substrate treating apparatus comprising:
a chamber having a treating space;
a support unit configured to support and heat a substrate in the treating space; and
a plasma source generating a plasma for treating the substrate, and
wherein the support unit comprises:
at least one heating element adjusting a temperature of the substrate;
a power source generating a power applied to the at least one heating element;
a power supply line transmitting the power to the at least one heating element;
a power return line grounding the at least one heating element; and
a current measuring resistor provided on the power supply line or the power return line and used for estimating a temperature of the at least one heating element.

15. The substrate treating apparatus of claim 14, wherein a ratio of magnitude of resistance of the current measuring resistor to magnitude of resistance of the at least one heating element is about 1:1000˜1:15000.

16. The substrate treating apparatus of claim 14, wherein the support unit comprises a first plate and a second plate disposed below the first plate, and
wherein the first plate comprises:
an insulation layer within which the at least one heating element is buried; and
a dielectric layer within which an electrostatic electrode for electrostatically clamping the substrate is buried, and
wherein the second plate has a fluid channel through which a cooling fluid flows.

17. The substrate treating apparatus of claim 16, wherein the current measuring resistor is positioned outside the insulation layer.

18. The substrate treating apparatus of claim 16, further comprising a control unit configured to control the support unit, and
wherein the control unit comprises:
a resistance measuring unit configured to measure a current flowing through the current measuring resistor and measure magnitude of resistance of the at least one heating element based on the measured current; and
a temperature estimation unit configured to estimate the temperature of the at least one heating element based on the magnitude of resistance of the heating element measured by the resistance measuring unit.

19. The substrate treating apparatus of claim 16, wherein the control unit comprises a control part configured to feedback control the temperature of the at least one heating element based on the estimated temperature of the at least one heating element estimated by the temperature estimation unit.

20. (canceled)
